(19) United States
(12) Patent Application Publication
(10) Pub. No.: US 2013/0056349 A1
(43) Pub. Date: Mar. 7, 2013

(54) SPUTTERING TARGET AND METHOD OF MANUFACTURING MAGNETIC MEMORY USING THE SAME

(71) Applicants: Eiji KITAGAWA, Yokohama-shi (JP); Tadaomi DAIBOU, Yokohama-shi (JP); Kenji NOMA, Yokohama-shi (JP); Tadashi KAI, Tokyo (JP); Koji YAMAKAWA, Tokyo (JP); Toshihiko NAGASE, Tokyo (JP); Katsuya NISHIYAMA, Yokohama-shi (JP); Koji UEDA, Fukuoka-shi (JP); Daisuke WATANABE, Yokohama-shi (JP); Hiroaki YODA, Kawasaki-shi (JP); Satoru SANO, Ube-shi (JP); Yoshihiro NISHIMURA, Ube-shi (JP); Takayuki WATANABE, Ube-shi (JP); Yuzo KATO, Ube-shi (JP); Akira UEKI, Ube-shi (JP)

(72) Inventors: Eiji KITAGAWA, Yokohama-shi (JP); Tadaomi DAIBOU, Yokohama-shi (JP); Kenji NOMA, Yokohama-shi (JP); Tadashi KAI, Tokyo (JP); Koji YAMAKAWA, Tokyo (JP); Toshihiko NAGASE, Tokyo (JP); Katsuya NISHIYAMA, Yokohama-shi (JP); Koji UEDA, Fukuoka-shi (JP); Daisuke WATANABE, Yokohama-shi (JP); Hiroaki YODA, Kawasaki-shi (JP); Satoru SANO, Ube-shi (JP); Yoshihiro NISHIMURA, Ube-shi (JP); Takayuki WATANABE, Ube-shi (JP); Yuzo KATO, Ube-shi (JP); Akira UEKI, Ube-shi (JP)

(21) Appl. No.: 13/600,812

(22) Filed: Aug. 31, 2012

(30) Foreign Application Priority Data
Sep. 1, 2011 (JP) 2011-190868

(51) Int. Cl. C23C 14/08; C23C 14/35

(52) U.S. Cl. 204/192.15; 204/298.13

(57) ABSTRACT

Provided are a sputtering target including a target main body 10 that has MgO as a main component and a thickness of 3 mm or smaller, and a method of manufacturing a magnetic memory using the sputtering target which improves an MR ratio.

### CROSS-REFERENCE TO RELATED APPLICATIONS

This application is based upon and claims the benefit of priority from the prior Japanese Patent Application No. 2011-190868, filed on Sep. 1, 2011, the entire contents of which are incorporated herein by reference.

### FIELD

Embodiments described herein relate to a sputtering target and a method of manufacturing a magnetic memory using the same.

### BACKGROUND

Historically, studies on a tunnel magnetic resistance (TMR) effect started from a research reported by Julliere et al. in 1975 and reach the development of 600% of magnetic resistance ratio of CoFeB/MgO/CoFeB junction in 2006 through the invention of 20% of magnetic resistance ratio at a room temperature by Miyazaki et al. in 1995. In recent years, product development using the above-mentioned technology is accelerated and a TMR effect that uses an MgO tunnel barrier layer is adopted in the field of an HDD magnetic head and spread in the market. Also, in a field of a magnetic random access memory (MRAM), a spin injection type TMR element using an MgO tunnel barrier layer has been actively researched and developed and accepted as a technology achieving both improvement of a reading resistance ratio and reduction of a writing current.

In the meantime, a development of a memory in the MRAM needs to be accompanied with a trend of low power consumption and low cost by miniaturization led by a Si device. From a view point of miniaturization and low power consumption, the lowering of a resistance of a MgO tunnel barrier layer is a requirement. For example, if 1 Gbit level of a general purpose memory is aimed, an element resistance RA of a MgO tunnel barrier layer is around 10 Ωμm² and a thickness of the MgO tunnel barrier layer is approximately 1 nm.

### BRIEF DESCRIPTION OF THE DRAWINGS

FIG. 1 is a front cross-sectional view of a sputtering target according to a first embodiment;

FIG. 2 is a front cross-sectional view of a sputtering target according to a second embodiment;

FIG. 3 is a front cross-sectional view of a sputtering target according to a third embodiment;

FIG. 4 is a graph illustrating an average sheath voltage (V_{dc}) for a thickness of a target main body (MgO);

FIG. 5 is a graph illustrating an MR ratio for a total thickness of a target main body (MgO) and a backing plate;

FIG. 6 is a conceptual diagram illustrating a structure of a perpendicular magnetized MTJ element manufactured using a sputtering target according to the first embodiment;

FIG. 7 is a graph illustrating a result of CIPT measurement in a perpendicular TMR film manufactured using a sputtering target according to the first and second embodiments;

FIG. 8 is a table illustrating a result of evaluating an impurity element in a MgO film formed by sputtering of a sputtering target according to each the first and second embodiments by performing ICP-MS analysis;

FIG. 9 is a graph illustrating a result of CIPT measurement in a perpendicular TMR film manufactured using a sputtering target according to a third embodiment and a comparative embodiment;

FIG. 10 is a front cross-sectional view illustrating a status when a sputtering target according to the first embodiment is mounted in a sputtering device;

FIG. 11 is a front cross-sectional view illustrating a status when a sputtering target according to a fourth embodiment is mounted in a sputtering device;

FIG. 12 is a front cross-sectional view illustrating a status when a sputtering target according to a fifth embodiment is mounted in a sputtering device;

FIG. 13 is a front cross-sectional view illustrating a status when a sputtering target according to a sixth embodiment is mounted in a sputtering device;

FIG. 14 is a front cross-sectional view illustrating a status when a sputtering target according to a seventh embodiment is mounted in a sputtering device;

FIG. 15 is a circuit diagram illustrating a configuration of an MRAM according to an eighth embodiment; and

FIG. 16 is a cross-sectional view illustrating a configuration of an MRAM according to the eighth embodiment.

### DETAILED DESCRIPTION

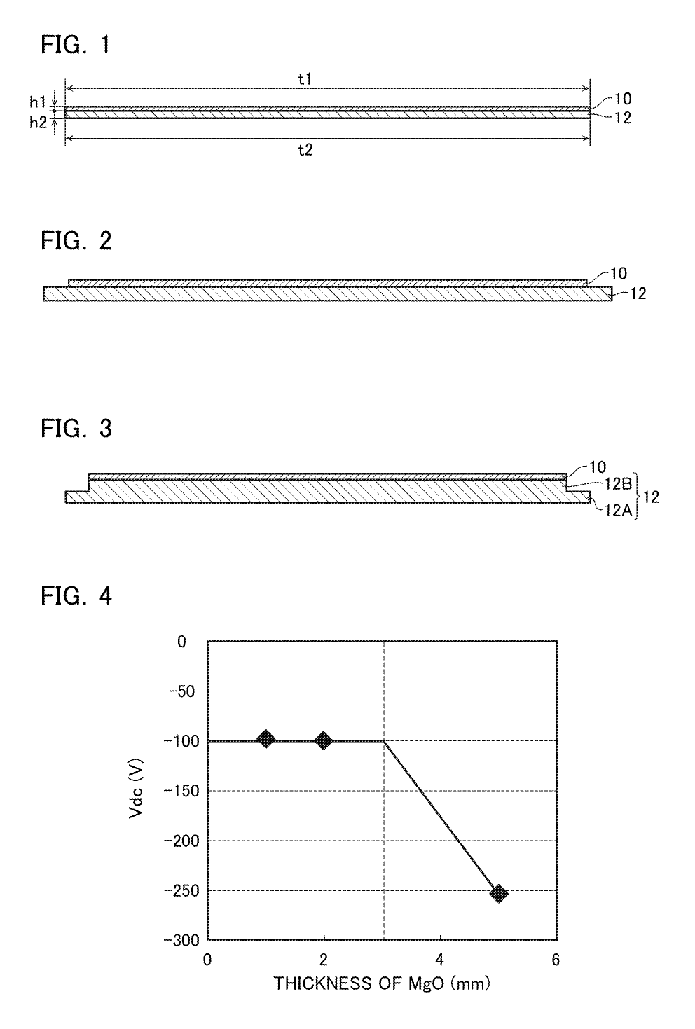

First, sputtering targets according to first to third embodiments will be described with reference to FIGS. 1 to 3. FIGS. 1 to 3 are front cross-sectional views of the sputtering targets, that is, illustrate faces perpendicular to faces to be sputtered. A sputtering target according to a first embodiment, as illustrated in FIG. 1, includes a disk shaped target main body 10 and a backing plate 12 which is formed in a disk shape having the same diameter as the target main body 10 and bonded to a bottom surface of the target main body 10 so as to overlap at the center thereof. In the first embodiment, outer diameters of the disk shaped target main body 10 and the backing plate 12, t1 and t2, are 180 mm, a thickness h1 of the target main body 10 is 1.5 mm, and a thickness h2 of the backing plate 12 is 2.5 mm. Further, in the embodiment, the outer diameter t1 of the target main body 10 may be larger than the outer diameter t2 of the backing plate 12.

A sputtering target according to a second embodiment, as illustrated in FIG. 2, is different from the first embodiment in that the outer diameter of the backing plate 12 is larger than the outer diameter of the target main body 10. In the second embodiment, the outer diameter of the target main body 10 is 164 mm and a thickness thereof is 2 mm. The outer diameter of the backing plate is 180 mm and the thickness thereof is 4 mm.

A sputtering target according to a third embodiment, as illustrated in FIG. 3 is different from the first and second embodiments in that the outer diameter of the target main body 10 is 164 mm, the thickness thereof is 1 mm, and the backing plate 12 has a disk shaped lower portion 12A having an outer diameter of 180 mm×a thickness of 4 mm and a disk shaped upper portion 12B which is formed to overlap at the center with a top surface of the lower portion 12A and has an outer diameter of 164 mm×a thickness of 3 mm.

In the sputtering targets according to the first to third embodiments, the target main bodies 10 have MgO as a main component. The MgO may be obtained by baking MgO powder compact at a high pressure using a sintering method and forming to have a predetermined shape. The MgO powder is refined by a wet refining process that refines magnesium hydroxide produced by a reaction of salty water and calcined lime and a gas-phase process that refines magnesium through oxidization. The gas-phase process is more desirable to obtain high-pure MgO powder having less impurity. Single crystal MgO may be used as MgO which is the main component of the target main body 10. By using the single crystal MgO, MgO which is close to the stoichiometric composition is sputtered to raise an MR ratio. However, since the single crystal MgO is processed at a high temperature during the grain growth process, an amount of impurity is larger than the polycrystalline MgO. Further, if a MgO tunnel barrier layer is made to have a low RA, the MR ratio is more significantly lowered as compared with a case when the polycrystalline MgO is used. Therefore, it is more desirable to use the polycrystalline MgO produced by the sintering method. MgO is desirably crystallized to have a NaCl structure and has a high density (99% or higher) and a small amount of elements other than MgO contained in MgO. In the first to third embodiments, the MgO powder using a gas-phase method is used as a raw material of MgO and MgO is produced by the sintering method.

In the sputtering target according to the first to third embodiments, as a material for the backing plate 12 to be used, for example, stainless steel, an Al alloy, a W alloy, or oxygen-free copper may be used. Generally, in the backing plate, the oxygen-free copper having an excellent thermal conductivity may be used. However, if the thickness of the backing plate is small, the rigidity of the oxygen-free copper is insufficient. Therefore, it is required to select a material that can ensure a sufficient rigidity in spite of having a small thickness. When an RF magnetron sputtering device is used to form the MgO tunnel barrier layer, it is desirable that a magnetic field generated from a magnet mounted at a cathode side is not weak. Therefore, the backing plate desirably has a high rigidity and a relative permeability of 1.2 or lower. Accordingly, in the first embodiment, as a non-magnetic stainless steel, SUS310S is used. In the usual non-magnetic SUS, when it is processed as a backing plate, magnetization may occur due to biased composition caused by rolling, overheating and the like. In contrast, the SUS310S represents a material having strong resistance to magnetization against the backing plate processing. Further, in the first embodiment, for example, a backing plate including both Nd₂Fe₁₄B and SUS having a magnetic anisotropy in a vertical direction may be used. Contrary to the non-magnetic stainless steel, by using a magnetic substance having a strong magnetic anisotropy in a cylindrical direction (vertical direction) for the backing plate, it is possible to make the magnetic field generated from the cathode magnet be stronger. In the sputtering target according to the second and third embodiments, as the material for the backing plate, oxygen-free copper is used. When the oxygen-free copper is used, the backing plate 12 is thick and may obtain a sufficient rigidity from the oxygen-free copper. When a thick backing plate is used, a material having a higher thermal conductivity is preferable.

In the first to third embodiments, the target main body 10 and the backing plate 12 are bonded by In. In the first embodiment, the target main body 10 and the backing plate 12 are formed so that the total of thicknesses of the target main body 10 and the backing plate 12 is 4 mm. Further, the sputtering targets according to the first to third embodiments may use only the target main body which is a MgO single body without using the backing plate. However, when the MgO single body is used, a strength of the target is lowered. Further, since the cooling efficiency of MgO is lowered, as the sputtering target, a backing plate which is bonded to MgO flakes is desirably used.

FIG. 4 illustrates an average sheath voltage (V_{dc}) with respect to the thickness of the target main body (MgO). By setting the thickness of the MgO to be 3 mm or smaller, it is possible to lower the absolute value of V_{dc}. Further, since V_{dc} indicates a leading-in voltage of an Ar ion, the absolute value of V_{dc} is desirably small.

A mechanism that lowers the absolute value of V_{dc} by setting the thickness of MgO to be small up to 3 mm will be described below. Since MgO is an insulator, MgO has an electrostatic capacitance C₁. If C₁ is increased by thinning MgO, the difference between C₁ and an electrostatic capacitance C₂ at the anode side becomes smaller. Since V_{dc} is proportional to the difference between C₁ and C₂, the difference between C₁ and C₂ becomes smaller by increasing C₁ by thinning MgO and thus the absolute value of V_{dc} is reduced. It is also considered that as the strength of a magnet in which plasma is confined is increased, a discharge stabilized electric field is reduced. It is considered that if the thickness of MgO is 3 mm or smaller, V_{dc} becomes constant because V_{dc} is determined depending on a discharge amount of secondary electrons discharged from MgO. A value of 3 mm which determines the lower limit of the absolute value of V_{dc} is a value determined by a material of the target main body (MgO). In the meantime, if the thickness of MgO becomes smaller, it is not possible to secure sufficient strength. As a result, a thickness of 0.1 mm or larger is required. In the embodiment, the thicknesses of the target main body and the backing plate are measured, for example, by a caliper or a micrometer.

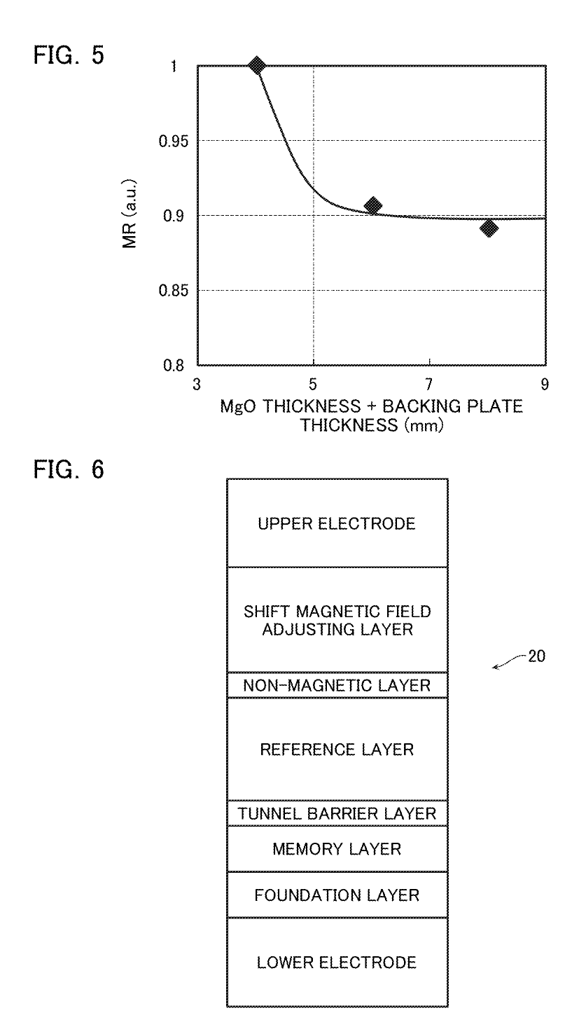

Further, FIG. 5 illustrates an MR ratio with respect to the total thicknesses of the target main body (MgO) and the backing plate. By making the total thickness of the MgO and the backing plate be smaller, a magnetic field strength generated by cathode magnets is increased and a plasma density of the Ar ion that sputters MgO is increased. If the plasma density is increased, the sputtering of jigs such as an earth shield provided around the sputtering target (neighboring jigs) may be reduced and a MgO tunnel barrier layer having less contaminated metal may be manufactured to obtain a high MR ratio. By setting the total thickness of the MgO and the backing plate to be 5 mm or smaller, the sufficiently high MR ratio may be obtained. In the meantime, if the total thickness of the MgO and the backing plate is smaller than 2 mm, there are problems in the strength of MgO and the backing plate, because MgO thermally expands while being discharged and breaks the target. Therefore, experimentally, the total thickness of the target main body and the backing plate is desirably 2 mm or larger and 5 mm or smaller.

The sputtering targets according to the first and second embodiments formed as described above are mounted in a sputtering device. Under an ultrahigh vacuum condition when a degree of vacuum in a non-sputtered state was 2×10⁻⁷ Pa, using an RF magnetron cathode and Ar gas, the Ar gas was ionized and is sputtered in MgO to discharge MgO and form the MgO tunnel barrier layer. The tunnel barrier layer is used to prepare a perpendicular TMR film. The perpendicular TMR film was used to prepare a perpendicular magnetized MTJ element 20. The perpendicular magnetized MTJ element 20, as illustrated in FIG. 6, is a representative perpendicular magnetized MTJ element including an upper electrode, a shift magnetic field adjusting layer, a non-magnetic layer, a reference layer (or a fixed layer, an anchoring layer, a fixing layer), a tunnel barrier layer, a memory layer (or a storage layer, a free layer), an foundation layer, and a lower electrode in this order from the upper electrode to the lower electrode. In the embodiment, the perpendicular magnetized MTJ element 20 having the structure of FIG. 6 is used to measure the MR ratio. By manufacturing the tunnel barrier layer of FIG. 6 using the sputtering target according to the embodiment, it is possible to obtain a high MR ratio. Further, the perpendicular magnetized MTJ element 20 of FIG. 6 is only an example. For example, if an MTJ element (not illustrated) having in-plane magnetization or an MTJ element (not illustrated) having a structure where the MgO tunnel barrier layer is inserted into a magnetic substance containing Fe or Co is used, the same effect may be obtained. In other words, the MTJ (magnetic tunnel junction) element having a magnetoresistance effect where tunnel current flows in the insulator and a resistance value is changed by applying a voltage may be used.

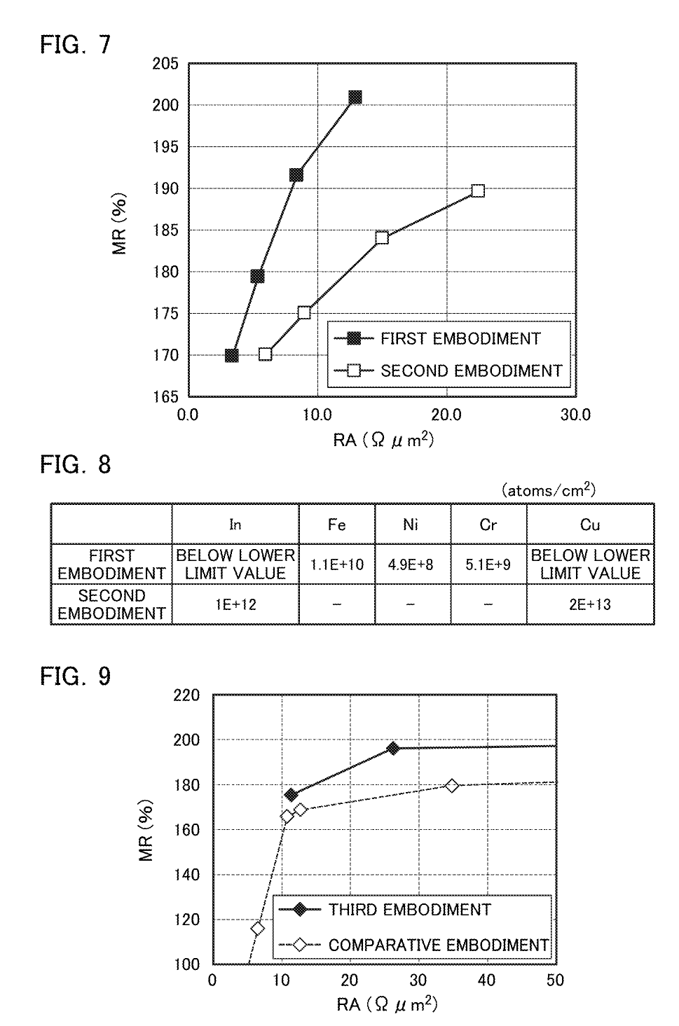

With respect to the perpendicular TMR film prepared using the sputtering targets according to the first and second embodiments, a current-in-plane tunneling (CIPT) measurement was performed (see Applied Physics Letters, Vol. 83, pp. 84 to 86). The result is illustrated in FIG. 7. When using the sputtering target according to the first embodiment, a higher MR ratio for all RA values than that of the sputtering target according to the second embodiment may be obtained. For example, in case of RA 10 Ωμm², when the sputtering target according to the first embodiment is used, the MR ratio is approximately 195%. When the sputtering target according to the second embodiment is used, the MR ratio is approximately 175%. Therefore, by using the sputtering target according to the first embodiment, it is possible to obtain the MR ratio approximately 20% higher than that of the sputtering target according to the second embodiment.

Using the sputtering targets according to the first and second embodiments, impurity elements in the MgO film formed by sputtering are evaluated by the ICP-MS analysis. The result is illustrated in FIG. 8. Since the sputtering target according to the first embodiment uses the SUS310S as the backing plate, component elements Fe, Cr, and Ni of the backing plate, a bonding material In, and comparative Cu are used as analytical elements. Since the sputtering target according to the second embodiment uses oxygen-free copper as the backing plate, Cu and In are analyzed as analytical elements. By using the sputtering target according to the first embodiment, an amount of contaminated metal due to the backing plate and the bonding material (In) contained in the MgO tunnel barrier layer may be reduced two or three digits compared with the sputtering target according to the second embodiment. When making the relationship of the outer diameter t1 of the target main body and the outer diameter t2 of the backing plate be t1=t2 or t1>t2, the backing plate and the bonding material are not exposed to the Ar plasma and thus the amount of contaminated metal due to the backing plate and the bonding material may be reduced. As a result, it is apparent from the first and second embodiments that a higher MR ratio may be obtained.

Next, as a comparison of the sputtering target according to a third embodiment, a sputtering target according to a comparative embodiment was prepared. Except that the thickness of the target main body is 5 mm, the sputtering target according to the comparative embodiment has the same configuration as the third embodiment. A perpendicular TMR film is formed and the CIPT measurement is performed by the same method as in the first embodiment using the sputtering targets according to the third embodiment and the comparative embodiment. The result is shown in FIG. 9. It is possible to obtain a higher MR ratio for all RA values of the sputtering target according to the third embodiment that uses a target main body having a thickness of 1 mm than that of the sputtering target according to the comparative embodiment that uses a target main body having a thickness of 5 mm. However, in case of both the sputtering target according to the third embodiment and the sputtering target according to the comparative embodiment, the outer diameter of the backing plate is larger than the outer diameter of the target main body. Further, the backing plate is exposed to Ar plasma and the contaminated metal due to the backing plate and the bonding material is contained. Even though both the sputtering targets are affected by the contaminated metal, the sputtering target according to the third embodiment obtains the higher MR ratio. This is because in the sputtering target according to the third embodiment, damage caused when Ar ion which is inserted in the MgO target main body by an average sheath voltage (V_{dc}) during the forming process of the MgO tunnel barrier layer sputters MgO and the MgO sputtered by the Ar ion collides on the MgO tunnel barrier layer is small and the biased composition caused when the coupling of MgO is broken in the sputtering process of MgO by the Ar ion and decoupled Mg and O reach the tunnel barrier layer is small. Further, in the sputtering target according to the third embodiment, it is hard to be affected by the plasma damage by a negative ion.

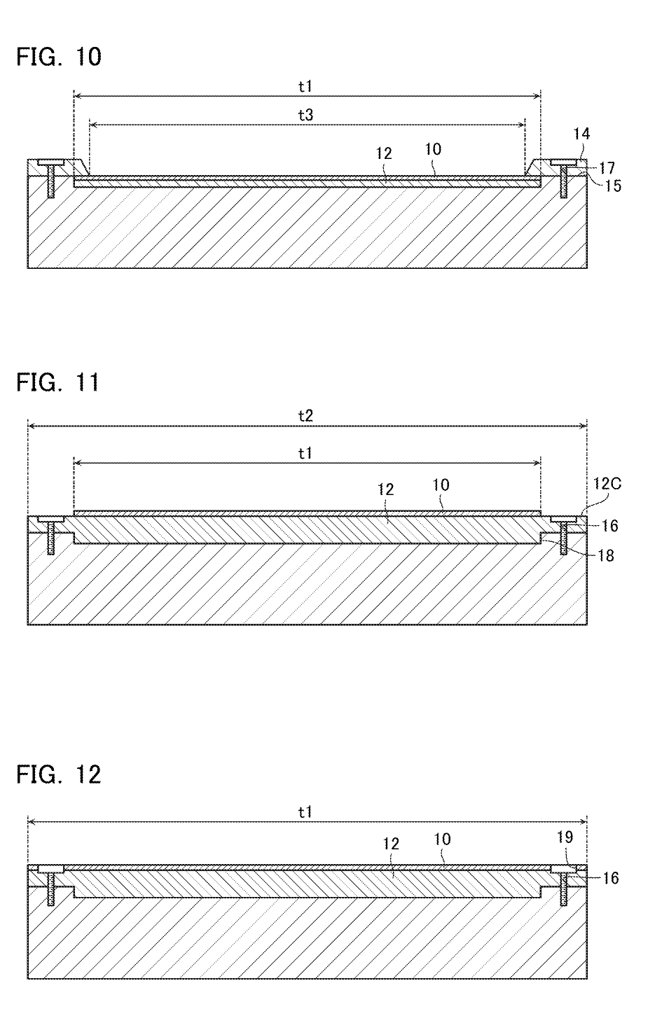

The sputtering target according to the first embodiment may be mounted in the sputtering device by a holder 14 having a smaller inner diameter than the outer diameter of the target main body 10 so as to expose a top surface of the target main body as illustrated in FIG. 10. Here, reference sign t1 denotes the outer diameter of the sputtering target according to the first embodiment and reference sign t3 denotes the inner diameter of the holder 14 that fixes the sputtering target according to the first embodiment to a cathode surface 15 of the sputtering device. The holder 14 that fixes the sputtering target has a screw hole 17 formed therein to be fixed to the cathode surface 15 through a screw. By using a thinner sputtering target according to the first embodiment, a higher MR ratio may be obtained.

The sputtering target according to the first embodiment after forming the MgO tunnel barrier layer has a black portion around an outer circumference. The black portion is an element sputtered from the holder and the screw fixing the sputtering target which is attached onto the top surface of the sputtering target according to the first embodiment. The attached element is mixed into the MgO tunnel barrier layer as a metal contamination element or serves as a cause of the particle, which are not preferable because the former causes the lowering of the MR ratio and the latter causes the lowering of the yield of the product. In the first embodiment, by making the thickness of the sputtering target be 5 mm or smaller, the plasma damage is lowered. Further, the neighboring jigs are not exposed to the plasma so that the amount of the contaminated metal other than MgO is reduced as small as possible during the sputtering, which contributes to increase MR. However, if the backing plate and the target main body (MgO) are formed to be thin, the magnetic field from the cathode magnet becomes stronger so that the amounts of electron and the Ar ion are increased. Further, the volume of the plasma formed on the top surface of the sputtering target is also increased. As a result, the distance between the holder 14 and the screw 17 and the plasma becomes closer and the influence of the contaminated metal by the holder 14 and the screw 17 is increased. In order to solve the problems, sputtering targets according to fourth to seventh embodiments are provided as described below.

A sputtering target according to a fourth embodiment, as illustrated in FIG. 11, includes a disk shaped target main body 10 having an outer diameter of 180 mm×a thickness of 2 mm and a backing plate 12 which is formed in a disk shape having a larger outer diameter t2 of the top surface than an outer diameter t1 of the target main body 10 and bonded to a bottom surface of the target main body 10 using In so as to overlap at the center thereof. At a side 12C of the top surface of the backing plate 12 which is outside the target main body 10, a hole for install a jig that fixes the backing plate 12 to the sputtering device, for example, a screw hole 16 through which an entire screw including a head of the screw is inserted is formed. Further, on the bottom surface of the backing plate 12, a cylindrical protruding portion 18 is formed and the outer circumference of the protruding portion 18 is formed so as to be inside the screw hole 16. Ina portion where the backing plate 12 of the sputtering device is mounted, a recessed portion into which the protruding portion 18 is fitted is formed. In the embodiment, a holder is not required and thus the influence by the contaminated metal caused by the holder does not exist. Further, by making the target main body 10 be larger in a radial direction as much as possible in the range where the target main body 10 is not in contact with the screw, it is possible to prevent the backing plate 12 from being sputtered to reduce the amount of impurity contained in the MgO tunnel barrier layer. The backing plate 12 desirably uses Cu or non-magnetic SUS. In the embodiment, there is no need to form a screw hole in the target main body 10 so that the target main body 10 may be produced at a low cost.

A sputtering target according to a fifth embodiment, as illustrated in FIG. 12, is different from the fourth embodiment in that an outer diameter t1 of the target main body 10 is the same as that of the backing plate 12, and at an outer edge vicinity of the target main body 10, that is, in a position to be matched with the screw hole 16 of the backing plate 12, a hole in which a jig is installed, for example, a screw hole 19 is formed so as to pass through the target main body 10 from the top surface to the bottom surface. The other configuration is the same as in the fourth embodiment. In the fifth embodiment, the area of MgO of the target main body may be increased so as to prevent the backing plate from being sputtered further than the fourth embodiment and reduce an amount of impurity contained in the MgO tunnel barrier layer. The backing plate uses desirably Cu or a non-magnetic SUS.

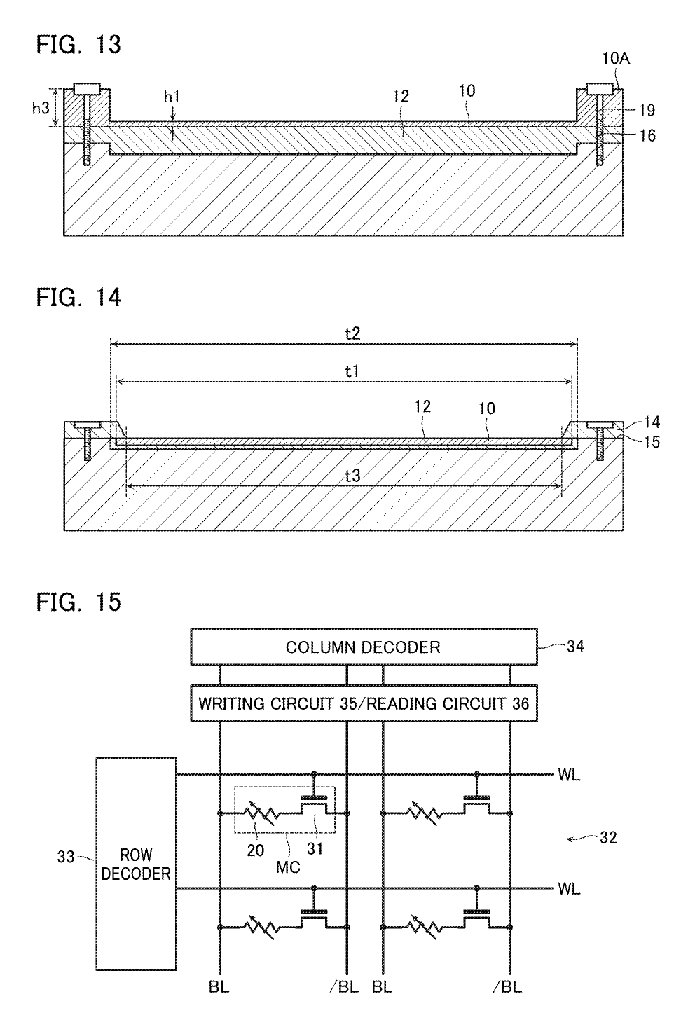

A sputtering target according to a sixth embodiment, as illustrated in FIG. 13, is different from the fifth embodiment in that an outer edge vicinity 10A including a screw hole 19 of the target main body 10 protrudes a top surface of the target main body 10 so as to be thicker than a portion inside the outer edge vicinity 10A. The other configuration is the same as in the fifth embodiment. In the sixth embodiment, the target main body 10 is formed such that a thickness of the outer edge vicinity is larger than that of the center portion. Therefore, it is possible to suppress the neighboring jig and the screw from being sputtered using the Ar ion. Further, a holder is not used and an area of the MgO of the target main body 10 may be increased. Thus, it is further possible to suppress the holder and the backing plate 12 from being sputtered. Accordingly, the influence of the contaminated metal may be suppressed and a higher MR ratio may be obtained compared to the fifth embodiment. In other words, in FIG. 13, reference sign h1 denotes a thickness of a center portion of the target main body, reference sign h3 denotes a thickness of the outer edge vicinity 10A of the target main body, and h1<h3. In the embodiment, the thickness of the outer edge vicinity of the target main body is larger than the thickness of a portion inside the outer edge vicinity by one step. However, an embodiment in which the thickness of the target is continuously changed or the thickness is changed through multiple steps may be used.

A sputtering target according to a seventh embodiment, as illustrated in FIG. 14, includes a disk shaped target main body 10 having an outer diameter of 180 mm×a thickness of 2 mm and a backing plate 12 which is formed in a disk shape having a larger outer diameter than that of the target main body 10 and bonded to a bottom surface of the target main body 10 using In so as to overlap at the center thereof. The sputtering target according to the seventh embodiment is pressed from the upper portion by a donut shaped holder 14 having an inner diameter t3 smaller than the outer diameter t1 of the target main body 10 to be mounted in a target device. In the sputtering target according to the seventh embodiment, a portion of the backing plate 12 outside the target main body 10 is configured such that a top surface thereof is thick to be on the same face as the top surface of the target main body 10. A force of the holder 14 that presses the target main body 10 is distributed by the thick portion so that the target main body 10 is hardly broken. The seventh embodiment is designed so as to satisfy the relationship of an inner diameter (t3) of the holder 14 that fixes the sputtering target<the outer diameter (t1) of the target main body<the outer diameter (t2) of the backing plate. Therefore, it is possible to prevent the bonding material that connects the target main body and the backing plate from being exposed. As a result, a high MR ratio may be obtained. The holder 14 that fixes the sputtering target is fixed to the cathode surface 15 by a screw.

As described above, using the sputtering targets according to the first to seventh embodiments, the perpendicular magnetized MTJ element 20 having a higher MR ratio may be formed. In other words, the sputtering targets according to the first to seventh embodiments may be appropriately used for a magnetic tunnel junction (MTJ) element.

An eighth embodiment relates to an MRAM (magnetic memory) configured by using the MTJ element 20 described above and has a circuit configuration illustrated in FIG. 15. The MRAM according to the eighth embodiment includes a memory cell array 32 having a plurality of memory cells MC arranged in a matrix. In the memory cell array 32, a plurality of bit line pairs BL and /BL are arranged so as to extend in a column direction. Further, in the memory cell array 32, a plurality of word lines WL are arranged so as to extend in a row direction.

At intersections of the bit lines BL and word lines WL, memory cells MC are arranged. Each of the memory cells MC includes an MTJ element 20 and a selective transistor 31. As the selective transistor 31, for example, an N channel MOS (metal oxide semiconductor) transistor is used. One end of the MTJ element 20 is connected to the bit line BL. The other end of the MTJ element 20 is connected to a drain of the selective transistor 31. A gate of the selective transistor 31 is connected to the word line WL. A source of the selective transistor 31 is connected to the bit line/BL.

A row decoder 33 is connected to the word lines WL. A writing circuit 35 and a reading circuit 36 are connected to the bit line pair BL and /BL. A column decoder 34 is connected to the writing circuit 35 and the reading circuit 36. The memory cells MC which are accessed at the time of writing data or reading data are selected by the row decoder 33 and the column decoder 34.

Next, data is written into the memory cells MC as described below. First, in order to select a memory cell MC that writes data, a word line WL connected to the memory cell MC is activated by a low decoder. By doing this, the selective transistor 31 is turned on. Further, the bit line pair BL and /BL connected to the selected memory cell MC is selected by the column decoder 34.

Here, one of bidirectional writing currents is supplied to the MTJ element 20 in accordance with writing data. Specifically, when the writing current is supplied to the MTJ element 20 from the left to the right of the drawing, the writing circuit 35 applies a positive voltage to the bit line BL and a ground voltage to the bit line/BL. Further, when the writing current is supplied to the MTJ element 20 from the right to the left of the drawing, the writing circuit 35 applies to the positive voltage to the bit line/BL and the ground voltage to the bit line BL. By doing this, data “0” or data “1” may be written in the memory cell MC.

Next, data is read from the memory cells MC as described below. First, similarly to the writing process, the selective transistor 31 of the selected memory cell MC is turned on. The reading circuit 36 supplies, for example, a reading current flowing from the right to the left of the drawing, to the MTJ element 20. The reading current is set to have a value lower than a threshold value that is inversely magnetized by spin injection. A sense amplifier included in the reading circuit 36 detects a resistance value of the MTJ element 20 based on the reading current. As described above, data stored in the MTJ element 20 may be read.

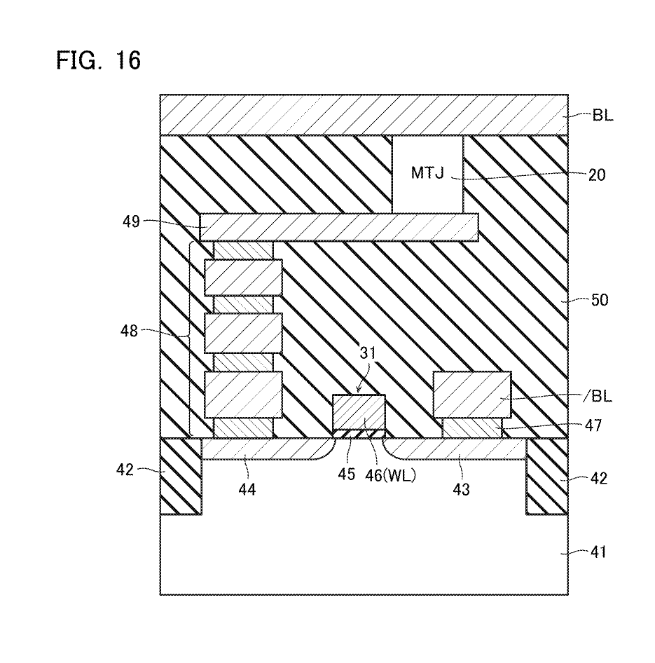

Next, a structure example of the MRAM will be described with reference to FIG. 16. A trench isolation insulating layer 42 having an STI (shallow trench isolation) structure is provided in a P type semiconductor substrate 41. In an element region (active region) enclosed by the trench isolation insulating layer 42, an N channel MOS transistor is provided as the selective transistor 31. The selective transistor 31 has diffusion regions 43 and 44 as a source/drain region, a gate insulating film 45 formed on the channel region between the diffusion regions 43 and 44, and a gate electrode 46 formed on the gate insulating film 45. The gate electrode 46 corresponds to the word line WL of FIG. 15.

On the diffusion region 43, a contact plug 47 is provided. On the contact plug 47, bit lines/BL are provided. On the diffusion region 44, a contact plug 48 is provided. On the contact plug 48, an extraction electrode 49 is provided. On the extraction electrode 49, the MTJ element 20 is provided. On the MTJ element 20, the bit line BL is provided. An interlayer insulating layer 50 is filled between the semiconductor substrate 41 and the bit line BL.

As described in detail above, the eight embodiment provides a method of manufacturing a magnetic tunnel junction element comprising forming a tunnel barrier layer by sputtering that uses any of the sputtering targets described in the first to seventh embodiments and forming a magnetic memory layer and a magnetic reference layer on respective surfaces that are in contact with the tunnel barrier layer.

Further, the eight embodiment provides a method of manufacturing a magnetic memory that has a plurality of memory cells each including a magnetic tunnel junction element, writes data into the memory cells and reads data from the memory cells comprising forming the tunnel barrier layer by sputtering that uses any of the sputtering targets described in the first to seventh embodiments and forming a magnetic memory layer and a magnetic reference layer on respective surfaces that are in contact with the tunnel barrier layer.

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A sputtering target, comprising:
a target main body that has MgO as a main component and a thickness of 3 mm or smaller.

2. The sputtering target according to claim. 1, wherein the sputtering target is for forming a magnetic tunnel junction element.

3. The sputtering target according to claim. 1, wherein the target main body is supported by a backing plate and a relationship between a thickness h1 of the target main body and a thickness h2 of the backing plate satisfies the following Equation (1).
[Equation 1]
h1+h2≦5 mm (1)

4. The sputtering target according to claim. 3, wherein the relationship between a thickness h1 of the target main body and a thickness h2 of the backing plate satisfies the following Equation (1)′.
[Equation 2]
2 mm≦h1+h2≦5 mm (1)′

5. The sputtering target according to claim. 3, wherein the backing plate is formed of any of stainless steel, an Al alloy, and a W alloy.

6. The sputtering target according to claim. 5, wherein the backing plate is stainless steel of SUS310S.

7. The sputtering target according to claim. 1, wherein the target main body is supported by the backing plate and a relationship between an outer diameter t1 of the target main body and an outer diameter t2 of the backing plate satisfies the following Equation (2).
[Equation 3]
t1≧t2 (2)

8. The sputtering target according to claim. 2, wherein the target main body is supported by the backing plate and a relationship between an outer diameter t1 of the target main body and an outer diameter t2 of the backing plate satisfies the following Equation (2).
[Equation 4]
t1≧t2 (2)

9. The sputtering target according to claim 1, wherein a hole configured to install a jig that fixes the sputtering target to a sputtering device in a state where a top surface of the target main body is exposed is formed at an outer edge vicinity of a top surface of the target main body.

10. The sputtering target according to claim 2, wherein a hole configured to install a jig that fixes the sputtering target to a sputtering device in a state where a top surface of the target main body is exposed is formed at an outer edge vicinity of a top surface of the target main body.

11. The sputtering target according to claim 1, wherein a relationship between a thickness h3 of an outer edge vicinity of the target main body and a thickness h1 of a portion inside the outer edge vicinity satisfies the following Equation (3).
[Equation 5]
h1<h3 (3)

12. The sputtering target according to claim 2, wherein the relationship between a thickness h3 of an outer edge vicinity of the target main body and a thickness h1 of a portion inside the outer edge vicinity satisfies the following Equation (3).
[Equation 6]
h1<h3 (3)

13. The sputtering target according to claim. 1, wherein the target main body is supported by the backing plate and a relationship between an outer diameter t1 of the target main body and an outer diameter t2 of the backing plate satisfies the following Equation (4), and
a hole configured to install a jig that fixes the sputtering target to a sputtering device is formed at a portion of a top surface of the backing plate outside the target main body.
[Equation 7]
t1<t2 (4)

14. The sputtering target according to claim 2, wherein the target main body is supported by the backing plate and a relationship between an outer diameter t1 of the target main body and an outer diameter t2 of the backing plate satisfies the following Equation (4), and
a hole configured to install a jig that fixes the sputtering target to a sputtering device is formed at a portion of a top surface of the backing plate outside the target main body.
[Equation 8]
t1<t2 (4)

15. The sputtering target according to claim 1, wherein the target main body is supported by the backing plate and a relationship between an outer diameter t1 of the target main body, an outer diameter t2 of the backing plate, and an inner diameter t3 of a donut shaped jig that fixes the sputtering target to a sputtering device in a state where a top surface of the target main body is exposed satisfies the following Equation (5), and
a portion of the backing plate outside the target main body is formed to be thicker than the other portion of the backing plate.
[Equation 9]
t3<t1<t2 (5)

16. The sputtering target according to claim 15, wherein a top surface of a portion of the backing plate outside the target main body is formed on the same face as a top surface of the target main body.

17. The sputtering target according to claim. 2, wherein the target main body is supported by the backing plate and a relationship between an outer diameter t1 of the target main body, an outer diameter t2 of the backing plate, and an inner diameter t3 of a donut shaped jig that fixes the sputtering target to a sputtering device in a state where a top surface of the target main body is exposed satisfies the following Equation (5), and
a portion of the backing plate outside the target main body is formed to be thicker than the other portion of the backing plate.
[Equation 10]
t3<t1<t2 (5)

18. A method of manufacturing a magnetic memory that has a plurality of memory cells each including a magnetic tunnel junction element, writes data into the memory cells and reads data from the memory cells comprising:
forming a tunnel barrier layer by sputtering that uses the sputtering target according to claim 1; and
forming a magnetic memory layer and a magnetic reference layer on respective surfaces in contact with the tunnel barrier layer.
